(19) United States
(12) Patent Application Publication
(10) Pub. No.: US 2026/0049390 A1
(43) Pub. Date: Feb. 19, 2026

(54) FILM FORMING APPARATUS AND FILM FORMING METHOD

(71) Applicant: JSW AFTY Corporation, Kanagawa (JP)

(72) Inventor: Hironori TORII, Kanagawa (JP)

(21) Appl. No.: 19/102,189

(22) PCT Filed: Jul. 28, 2023
(86) PCT No.: PCT/JP2023/027803

§ 371 Date: Feb. 7, 2025

(30) Foreign Application Priority Data
Aug. 9, 2022 (JP) 2022-126745
Jul. 21, 2023 (JP) 2023-119251

(51) Int. Cl. C23C 14/35; C23C 14/06

(52) U.S. Cl. CPC C23C 14/357; C23C 14/0617; C23C 14/352

(57) ABSTRACT

Utility of an ECR plasma technique is enhanced. A film forming apparatus 1 deposits, on a surface of a substrate SUB, first target particles emitted by bombardment of ions (ions making ECR plasma) with a cylindrical target TA mounted on a cylindrical-target mounting section 27 and second target particles emitted by bombardment of ions (ions making plasma which is different in density from the ECR plasma) with a disk target TA2 mounted on a disk-target mounting section 31.

### CROSS-REFERENCE TO RELATED APPLICATIONS

This application is a National Stage application of International Patent Application No. PCT/JP2023/027803, filed on Jul. 28, 2023, which claims priority to Japanese Patent Application No. 2022-126745, filed on Aug. 9, 2022, and Japanese Patent Application No. 2023-119251, filed on Jul. 21, 2023, each of which is hereby incorporated by reference in its entirety.

### TECHNICAL FIELD

The present invention relates to a film forming apparatus and a film forming technique, and relates to a technique effectively applied to, for example, a technique of forming a film on a substrate under use of plasma.

### BACKGROUND

Japanese Patent Application Laid-open Publication No. 2005-281726 (Patent Document 1) and Japanese Patent No. 7018702 (Patent Document 2) describe a technique for a film forming apparatus of forming a film on a sample substrate by evaporation or physical vapor deposition such as sputtering at the same time with plasma irradiation under use of electron cyclotron resonance.

Patent Document 1: Japanese Patent Application Laid-open Publication No. 2005-281726

Patent Document 2: Japanese Patent 7018702

### SUMMARY

There is an electron cyclotron resonance (ECR) sputtering technique of using ECR plasma generated with ECR phenomenon to form a film by bombardment of ions contained in the ECR plasma with a cylindrical target arranged around the ECR plasma, thereby adhering target particles emitted from the cylindrical target onto a substrate to form the film.

The ECR sputtering technique is advantageous in that a high-quality film can be formed on a substrate since the film can be formed under ion irradiation having low energy and high density. To the contrary, the ECR sputtering technique is disadvantageous in that a film forming speed of the film formed on the substrate is lower than that in a typical magnetron sputtering technique or the like as a result of a lower density of the target particles adhering to the substrate than that.

In this regard, an approach to enhance utility of the ECR sputtering technique by a devisal for eliminating the disadvantages of the ECR sputtering technique is considerable. However, as the approach to enhance the utility of the ECR sputtering technique, not only this devisal but also a devisal for changing the disadvantages of the ECR sputtering technique to the advantages is considerable.

Accordingly, the present inventors have employed the approach with the devisal for changing the disadvantages of the ECR sputtering technique to the advantages. Further, in the employment of this approach, a devisal for enhancing the utility of the ECR sputtering technique is desirable.

For example, in the fields of power semiconductors and semiconductor lasers, semiconductor elements each using a compound semiconductor material have been developed. As a specific compound, gallium nitride (GaN) is exemplified. The gallium nitride has a property being wider in band gap than silicon, and therefore, being higher in breakdown electric field intensity than silicon. Additionally, due to a wider band gap, a nitride semiconductor material has a property emitting a light with a wavelength in the ultraviolet light band when electrons transit from the conduction band to the valance band.

Thus, in attention to, for example, the field of the power semiconductor, the power transistors such as power metal oxide semiconductor field effect transistor (MOSFET) and insulated gate bipolar transistor (IGBT) made of gallium nitride have been studied. This is because the power transistor using gallium nitride achieves the same breakdown voltage with that of the power transistor using silicon by a remarkably thin breakdown voltage layer since the gallium nitride is wider in band gap than silicon. That is, achievement of a small thickness of the breakdown voltage layer means achievement of a small ON resistance, and therefore, the power transistor using gallium nitride is excellent in achievement of both the improved breakdown voltage and the small ON resistance, both of which are in a trade-off relation.

Further, in attention to, for example, the field of the semiconductor laser, formation of a semiconductor laser with a wavelength in the ultraviolet light band from AlGaN has been made.

Here, in order to achieve the semiconductor element using gallium nitride, an n-type semiconductor material, a p-type semiconductor material, AlGaN, and the like in which gallium nitride is used as a base material, are used.

Specifically, the material to be used is an n-type semiconductor material in which silicon as an n-type impurity (donor) is added to gallium nitride, a p-type semiconductor material in which magnesium as a p-type impurity (acceptor) is added to gallium nitride, AlGaN in which aluminum is added to gallium nitride, or the like.

The explanation described here is made while exemplifying gallium nitride (compound semiconductor material) as the specific semiconductor material. However, the present invention is not limited to this. In the power transistors and the semiconductor elements typified by the semiconductor lasers using a wide variety of semiconductor materials, in order to achieve performance of the semiconductor element, it is necessary to use a semiconductor film accurately controlled in terms of a composition ratio of the conductive impurity.

In this regard, if a technique of forming the semiconductor film accurately controlled in terms of the composition ratio is achieved under use of the ECR sputtering technique, the utility of the ECR sputtering technique can be enhanced. Thereby, in attention to, for example, achievement of the technique of forming the semiconductor film accurately controlled in the composition ratio, a devisal for enhancing the utility of the ECR sputtering technique is desirable.

A film forming apparatus according to one embodiment includes: a first plasma generating section configured to generate ECR plasma; and a cylindrical-target mounting section configured to mount a cylindrical target to be bombarded with ions making the ECR plasma generated in the first plasma generating section. The film forming apparatus further includes: a second plasma generating section configured to generate plasma which is different in density from the ECR plasma; and a disk-target mounting section configured to mount a disk target to be bombarded with ions making the plasma generated in the second plasma generating section. The film forming apparatus further includes a sample stage configured to place a substrate on which first target particles emitted by the bombardment of the ions with the cylindrical target mounted on the cylindrical-target mounting section are to be deposited and on which second target particles emitted by the bombardment of the ions with the disk target mounted on the disk-target mounting section are to be deposited.

A film forming method according to one embodiment includes: a step of mounting a cylindrical target on a cylindrical-target mounting section; a step of mounting a disk target on a disk-target mounting section; a step of generating ECR plasma; and a step of generating plasma which is different in density from the ECR plasma. The film forming method further includes a step of depositing, on a substrate, first target particles emitted by bombardment of first ions making the ECR plasma with the cylindrical target mounted on the cylindrical-target mounting section, and depositing, on the substrate, second target particles emitted by bombardment of second ions making the plasma with the disk target mounted on the disk-target mounting section, to form a film containing the first target particles and the second target particles on the substrate.

According to one embodiment, utility of an ECR plasma technique can be enhanced.

### BRIEF DESCRIPTIONS OF THE DRAWINGS

FIG. 1 is a schematic diagram illustrating an outer configuration of a cylindrical target used in a film forming apparatus.

FIG. 2 is a diagram for schematically explaining a state in which use of a disk target easily damages a substrate.

FIG. 3 is a diagram for explaining a state in which use of a cylindrical target causes less damage to the substrate.

FIG. 4 is a table illustrating advantages and disadvantages under use of each of the cylindrical target and the disk target.

FIG. 5 is a diagram illustrating a schematic configuration of a film forming apparatus according to an embodied aspect.

FIG. 6 is a flowchart for explaining a flow of a first operation.

FIG. 7 is a flowchart for explaining a flow of a second operation.

FIG. 8 is a diagram illustrating a portion subjected to SIMS analysis in a substrate on which a film is formed.

FIG. 9 is a graph illustrating a relationship between a thickness of an amorphous silicon film formed on a substrate and a position on the substrate.

FIG. 10 is a graph illustrating a relationship between a silicon concentration and a depth.

FIG. 11 is a graph illustrating a relationship between a magnesium concentration and a depth.

FIG. 12 is a graph illustrating a relationship between an aluminum concentration and a depth.

### DETAILED DESCRIPTION

The same components are denoted by the same reference symbols in principle throughout all the drawings for describing the embodiments, and the repetitive description thereof will be omitted. Also, even a plan view may be hatched so as to make the drawings easy to see.

### Advantages of Cylindrical Target

The cylindrical target is used for a film forming apparatus in which an ECR sputtering technique is embodied. To the contrary, the disk target is used for a film forming apparatus in which a typical sputtering technique such as an RF sputtering technique or a magnetron sputtering technique is embodied.

FIG. 1 is a schematic diagram illustrating an outer configuration of a cylindrical target TA used for the film forming apparatus.

As illustrated in FIG. 1, the cylindrical target TA is cylindrical. Specifically, the cylindrical target TA includes, for example, a cylindrical backing tube (supporting member) 100 made of a copper material, and a cylindrical target member 110 is bonded to the inner wall of the backing tube 100 by a bonding material (adhesive) not illustrated.

The cylindrical target TA configured as described above causes less damage to a substrate SUB than that of a generally-available disk target. The advantages of this will be described below.

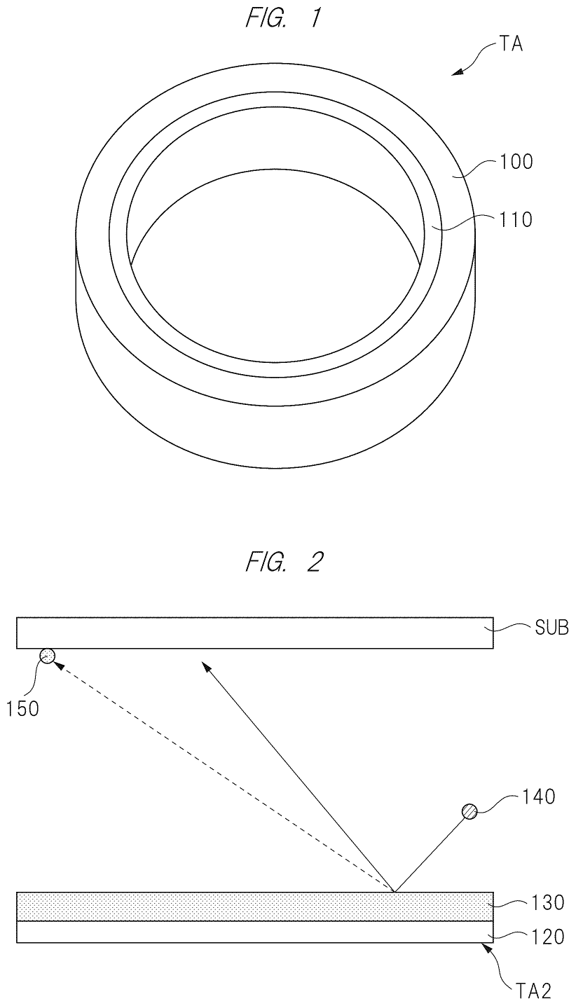

FIG. 2 is a diagram for schematically explaining a state in which the use of the disk target easily damages the substrate. In FIG. 2, a disk target TA2 is arranged to face the substrate SUB. The disk target TA2 includes a supporting member 120 and a target member 130 arranged on the supporting member 120. The target member 130 is a member with which positive ions are bombarded, and the positive ions are, for example, argon ions, nitrogen ions, krypton ions, xenon ions or the like.

Here, for example, as illustrated in FIG. 2, when positive ions 140 with kinetic energy are bombarded with the target member 130, target particles 150 emit from the target member 130, and adhere to a surface of the substrate SUB. Thereby, a film made of the target particles 150 is formed on the surface of the substrate SUB.

At this time, note that the positive ions 140 having high energy bombard with the target member 130 also recoil. As illustrated in FIG. 2, under the use of the disk target TA2, the substrate SUB is arranged to face the disk target TA2. Thus, as illustrated in FIG. 2, the recoil positive ions 140 having high energy also easily bombard with the substrate SUB. That is, under the use of the disk target TA2, when the film is formed on the surface of the substrate SUB facing the disk target TA2, not only the target particles 150 to be constituent elements of the film but also the recoil positive ions 140 having high energy easily bombard with the surface of the substrate SUB.

Thereby, the film forming apparatus of forming the film on the surface of the substrate SUB facing the disk target TA2 under the use of the disk target TA2 has a large probability of the bombardment of the recoil positive ions 140 having high energy with the substrate SUB, and thus, easily damages the substrate SUB due to the recoil positive ions 140 having high energy.

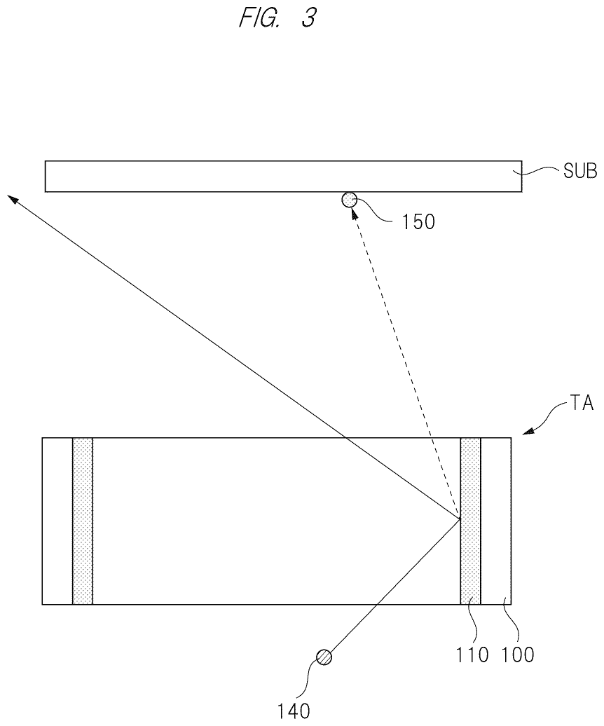

To the contrary, FIG. 3 is a diagram for explaining a state in which the use of the cylindrical target TA causes less damage to the substrate SUB. In FIG. 3, the cylindrical target TA is arranged to face the substrate SUB. Further, the cylindrical target member 110 is arranged on the inner wall of the cylindrical backing tube 100 in the cylindrical target TA. Therefore, in the cylindrical target TA of FIG. 3, the target member 110 is not arranged to face the substrate SUB.

At this time, as illustrated in FIG. 3, even in the cylindrical target TA, as a result of the bombardment of the positive ions 140 with kinetic energy with the target member 110, the target particles 150 emit from the target member 110, and adhere to the surface of the substrate SUB. Consequently, even under the use of the cylindrical target TA, the film made of the target particles 150 can be formed on the surface of the substrate SUB.

To the contrary, the cylindrical target TA illustrated in FIG. 3 is different from the disk target TA2 illustrated in FIG. 2 in that the target member 110 itself is not arranged to face the substrate SUB.

Thereby, as illustrated in FIG. 3, the cylindrical target TA has a smaller probability of the bombardment of the recoil positive ions 140 having high energy with the substrate SUB after the bombardment with the target member 110.

Therefore, the film forming apparatus of forming the film on the surface of the substrate SUB under the use of the cylindrical target TA has a small probability of the bombardment of the recoil positive ions 140 with the substrate SUB, and thus, can reduce the damage of the bombardment of the recoil positive ions 140 having high energy onto the substrate SUB.

As described above, the cylindrical target TA illustrated in FIG. 3 is more advantageous than the generally-used disk target TA2 (see FIG. 2) in that it causes less damage to the substrate SUB. However, as a result of studies made by the present inventors, it has been found that the film forming apparatus under the use of the cylindrical target TA has the following disadvantages.

### Disadvantages of Cylindrical Target

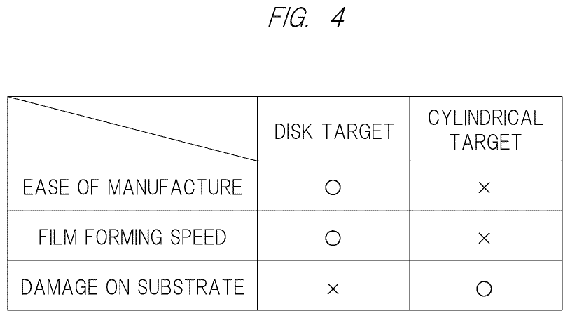

FIG. 4 is a table illustrating advantages and disadvantages under the use of each of the cylindrical target and the disk target. As illustrated in FIG. 4, the use of the cylindrical target can cause the less damage to the substrate than that of the use of the disk target. That is, the use of the cylindrical target is advantageous in that it causes the less damage to the substrate.

To the contrary, as illustrated in FIG. 4, the disk target is more excellent than the cylindrical target in a target price, ease of manufacture, and a film forming speed. In other words, the cylindrical target is disadvantageous in that (1) its manufacturing is more difficult than that of the disk target, and in that (2) it is lower in the film forming speed than that of the disk target. In this regard, based on the premise that the present inventors employ the approach with the devisal for changing the disadvantages of the ECR sputtering technique to the advantages, the present inventors have made the devisal for enhancing the utility of the ECR sputtering technique in the employment of the approach. The technical idea with the devisal will be described below.

### Basic Idea (Generic Concept) of Embodiment

Based on the premise that the first target particles and the second target particles are deposited on the substrate, the basic idea of the present embodiment is an idea employing the ECR sputtering technique under the use of the cylindrical target for depositing the first target particles while employing the ECR sputtering technique under the use of the disk target for depositing the second target particles.

That is, the basic idea is an idea in a combination of the ECR sputtering technique under the use of the cylindrical target and the ECR plasma and the sputtering technique under the use of the disk target and the plasma different in density from the ECR plasma.

Particularly in attention to the film forming speed, the basic idea is effective in a case in which the film to be deposited on the substrate is made of the combination of the first target particles and the second target particles so as to employ a material for the first target, for which a high film forming speed is not required, and employ a material for the second target, for which the high film forming speed is required. This is because, in this case, the low film forming speed that is one of the disadvantages of the ECR sputtering technique under the use of the cylindrical target is eliminated by the employment of the material for the first target particles, for which the high film forming speed is not required. That is, not the ECR sputtering technique under the use of the cylindrical target but the sputtering technique under the use of the disk target is employed for the material for which the high film forming speed is required, thereby securing the film forming speed. Thus, the basic idea can make less potential of the low film forming speed that is one of the disadvantages of the ECR sputtering technique under the use of the cylindrical target. Additionally, if the employment of the ECR sputtering technique under the use of the cylindrical target is advantageous as the technique for depositing the first target particles on the substrate, the approach to change the disadvantages of the ECR sputtering technique to the advantages is achieved, and the utility of the ECR sputtering technique can be enhanced.

Further, in attention to the ease of the target manufacturing, the basic idea is also effective in a case in which the film to be deposited on the substrate is made of the combination of the first target particles and the second target particles so as to employ a material for the first target particles, which is easy to form the cylindrical target, and employ a material for the second target particles, which is difficult to form the cylindrical target. This is because, in the employment of the material for the second target, which is difficult to form the cylindrical target, the ease of the target manufacturing can be secured when the second target is made of not the cylindrical target but the disk target excellent in the ease of the target manufacturing. That is, this is because the difficulty in the target manufacturing that is the disadvantage of the ECR sputtering technique under the use of the cylindrical target is eliminated by the employment of not the cylindrical target but the disk target for the second target. That is, not the ECR sputtering technique under the use of the cylindrical target but the sputtering technique under the use of the disk target is employed for the material which is difficult to form the cylindrical target, thereby avoiding the difficulty in the target manufacturing.

Thus, the basic idea can prevent appearance of the difficulty in the target manufacturing that is the disadvantage of the ECR sputtering technique under the use of the cylindrical target. Additionally, if the employment of the ECR sputtering technique under the use of the cylindrical target is advantageous for the first target, the approach to change the disadvantages of the ECR sputtering technique to the advantages is achieved, and the utility of the ECR sputtering technique can be enhanced.

### Basic Idea (Intermediate Concept) of Embodiment

As described above, in attention to the film forming speed, the basic idea is effective in a case in which the film to be deposited on the substrate is made of the combination of the first target particles and the second target particles so as to employ a material for the first target particles, for which the high film forming speed is not required, and employ a material for the second target particles, for which the high film forming speed is required.

Specifically, it is considerable that, for example, a film in which a doping material is added to a base material is a candidate of the film to be deposited on the substrate. Further, in this case, it can be said that the basic idea is an idea employing the ECR sputtering technique under the use of the cylindrical target for depositing the doping material and employing the sputtering technique under the use of the disk target for depositing the base material.

In this case, the doping material is not a main component of the film to be deposited on the substrate but the added component. Thus, for the doping material, the film forming speed is not required to be high so much. That is, it can be said that the doping material is a material, for which the high film forming speed is not required.

To the contrary, the base material is the main component of the film to be deposited on the substrate, and thus, the high film forming speed is required for depositing the base material. That is, it can be said that the base material is a material, for which the high film forming speed is required. Therefore, in the employment of the basic idea for depositing the film with the doping material added to the base material, on the substrate, the ECR sputtering technique under the use of the cylindrical target is employed for depositing the doping material, while the sputtering technique under the use of the disk target is employed for depositing the base material. Thereby, by the employment of the doping material for the first target particles, for which the high film forming speed is not required, the low film forming speed that is one of the disadvantages of the ECR sputtering technique under the use of the cylindrical target is eliminated from the disadvantages.

In other words, the film forming speed can be secured by the employment of not the ECR sputtering technique under the use of the cylindrical target but the sputtering technique under the use of the disk target for the base material, for which the high film forming speed is required.

From the above, by the employment of the basic idea for depositing the film with the doping material added to the base material, the low film forming speed that is one of the disadvantages of the ECR sputtering technique under the use of the cylindrical target is prevented from being problematic. Additionally, if the employment of the ECR sputtering technique under the use of the cylindrical target is advantageous as a technique of depositing the doping material on the substrate, the approach to change the disadvantages of the ECR sputtering technique to the advantages is achieved, and the utility of the ECR sputtering technique can be enhanced.

Specifically, the employment of the ECR sputtering technique under the use of the cylindrical target is advantageous as the technique of depositing the doping material on the substrate. The advantage will be described below.

For example, the sputtering technique under the use of the disk target is employed as the depositing technique of the base material onto the substrate. Specifically, the sputtering technique is a sputtering technique such as a magnetron sputtering technique or an RF sputtering technique (also called typical sputtering technique below) under use of plasma which is different in density from the ECR plasma. In the typical sputtering technique, large power is supplied from a sputtering power supply to the target. This is because the typical sputtering technique generates the plasma under use of the large power supplied from the sputtering power supply to the target. Thereby, for example, when the typical sputtering technique is employed to deposit the doping material on the substrate, the addition amount of the doping material is difficult to be controlled to be small due to the application of the large power to the disk target. That is, in the typical sputtering technique, since the addition amount of the doping material is very small, the (very small) addition amount of the doping material is difficult to be accurately controlled with the large power supplied from the sputtering power supply.

To the contrary, in the employment of the ECR sputtering technique under the use of the cylindrical target for the technique of depositing the doping material on the substrate, the ECR sputtering technique generates the ECR plasma under use of the electron cyclotron resonance phenomenon. Thus, the power supplied from the sputtering power supply to the cylindrical target can be made smaller than the power supplied from the sputtering power supply to the disk target in the typical sputtering technique. This is because the ECR sputtering technique does not generate the ECR plasma under the use of the power supplied from the sputtering power supply to the cylindrical target.

Therefore, in the ECR sputtering technique, the power supplied from the sputtering power supply to the cylindrical target can be made small, and thus, target particles (particles making the doping material) emitted from the cylindrical target can be made less. This means that the addition concentration of the doping material is easy to be accurately controlled to be small by the small power supplied from the sputtering power supply to the cylindrical target. That is, the ECR sputtering technique is advantageous in that the (very small) addition amount of the doping material can be accurately controlled by controlling the small power supplied from the sputtering power supply to the cylindrical target. As described above, according to the basic idea, by the employment of the ECR sputtering technique under the use of the cylindrical target for the technique of depositing the doping material on the substrate, the disadvantage of the ECR sputtering technique which is the low film forming speed can be changed to the advantage that is the accurate control for the (very small) addition amount of the doping material. Consequently, according to the basic idea, the utility of the ECR sputtering technique can be enhanced.

### Basic Idea (Specific Concept) of Embodiment

As described above, in the employment of the basic idea, for example, the film with the doping material added to the base material is considerable as the film to be deposited on the substrate. More specifically, employment of gallium nitride (GaN) for the base material and employment of silicon (Si), magnesium (Mg), or aluminum (Al) for the doping material are considerable.

In this case, gallium nitride is a semiconductor material. Additionally, addition of silicon to gallium nitride can produce an n-type semiconductor material, and addition of magnesium to gallium nitride can produce a p-type semiconductor material. Further, addition of aluminum to gallium nitride can produce AlGaN.

As described above, in the employment of gallium nitride for the base material and the employment of silicon, magnesium, or aluminum for the doping material, according to the basic idea, the disadvantage of the ECR sputtering technique which is the low film forming speed is changed to the advantage that is the accurate control for the (very small) addition amount of the doping material by the employment of the ECR sputtering technique under the use of the cylindrical target as the technique of depositing the doping material (silicon, magnesium, or aluminum) on the substrate. Consequently, according to the basic idea, the utility of the ECR sputtering technique can be enhanced.

Furthermore, in attention to the ease of the target manufacturing, the gallium nitride is a material that is difficult to form the cylindrical target. Therefore, the ease of the target manufacturing can be secured when the basic idea is employed so that the target made of gallium nitride is made of not the cylindrical target but the disk target excellent in the ease of the target manufacturing. That is, the difficulty in the target manufacturing that is the disadvantage of the ECR sputtering technique under the use of the cylindrical target is eliminated by the employment of not the cylindrical target but the disk target for the target made of gallium nitride. That is, not the ECR sputtering technique under the use of the cylindrical target but the typical sputtering technique under the use of the disk target is employed for the gallium nitride which is difficult to form the cylindrical target, thereby avoiding the difficulty in the target manufacturing.

To the contrary, silicon, magnesium, or aluminum as the doping material is a material that is low in cost for manufacturing the cylindrical target and easy to form he cylindrical target. Thus, the ECR sputtering technique under the use of the cylindrical target is employed for the technique of depositing silicon, magnesium, or aluminum as the doping material on the substrate. Thereby, according to the basic idea, the addition amount of the doping material can be accurately controlled, and, as a result, the utility of the ECR sputtering technique can be enhanced.

### Embodied Aspect

An embodied aspect in which the above-described basic idea is embodied will be described below.

### <<Configuration of Film Forming Apparatus>>

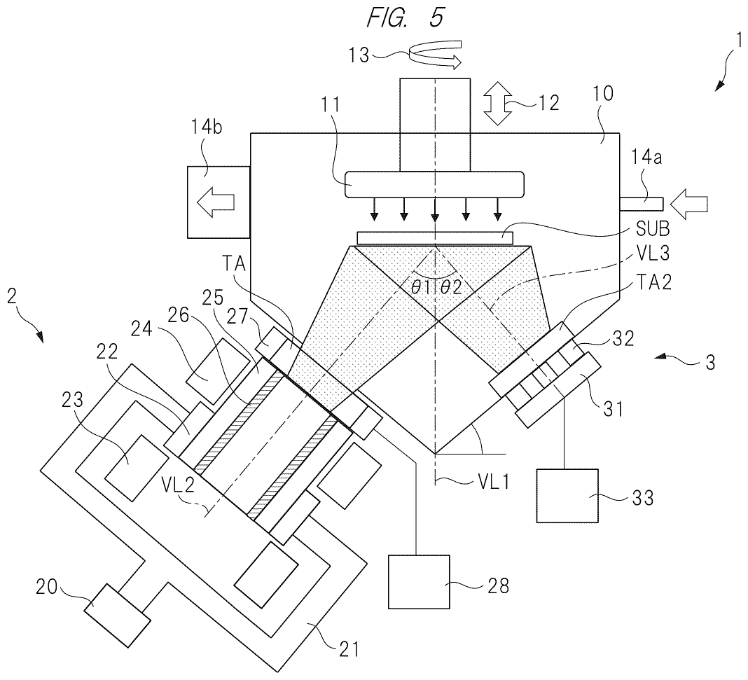

FIG. 5 is a diagram illustrating a schematic configuration of a film forming apparatus 1 according to the embodied aspect.

In FIG. 5, the film forming apparatus 1 includes a film forming chamber 10. The film forming chamber 10 is provided with a sample stage 11 on which a substrate SUB that is a film-formed object is placed. The sample stage 11 includes a vertical movement mechanism 12 for vertically moving the sample stage 11 and a rotation mechanism 13 for rotating the substrate SUB placed on the sample stage 11. The sample stage 11 further includes a heating mechanism for heating the substrate SUB. The film forming chamber 10 is further provided with a supply port 14a for introducing process gas and a vacuum evacuation mechanism 14b for making a pressure of the film forming chamber 10 close to the vacuum state.

The film forming apparatus 1 further includes an ECR sputtering section 2 connected to the film forming chamber 10. The ECR sputtering section 2 includes a microwave generator 20 for generating a microwave, a microwave waveguide 21 that is a propagating path for the microwave generated in the microwave generator 20, and a microwave introducing window 22 for introducing the microwave into an ECR plasma chamber 25. The ECR sputtering section 2 further includes the ECR plasma chamber 25 connected to the microwave introducing window 22, and the microwave emitted from the microwave introducing window 22 is introduced into the ECR plasma chamber 25.

In this case, according to the embodied aspect, as illustrated in FIG. 5, the microwave is introduced from a side surface of the ECR plasma chamber 25. That is, the film forming apparatus 1 is provided with the paired microwave waveguides 21 branching from the microwave generator 20, and each of the paired microwave introducing windows 22 is provided with the microwave waveguide 21.

Additionally, the microwave introducing windows 22 are provided on the facing side surfaces of the ECR plasma chamber 25, respectively, and the film forming apparatus 1 according to the embodied aspect employs a “branching-coupling plasma source.”

An anti-adhesive tube 26 is provided inside the ECR plasma chamber 25, and a coil 23 and a coil 24 for generating a magnetic field are arranged around the ECR plasma chamber 25.

For example, mixed gas of nitrogen gas and argon gas is introduced into the ECR plasma chamber 25, and the ECR plasma is generated from the mixed gas by the magnetic field generated by the coil 24 and the microwave introduced from the microwave introducing windows 22. That is, according to the embodied aspect, a plasma generating section (first plasma generating section) for generating the ECR plasma is made of the microwave generator 20, the microwave waveguides 21, the microwave introducing windows 22, the coil 23, the coil 24, and the ECR plasma chamber 25.

As described above, the plasma generating section includes: the microwave generator 20 for generating the microwave; the paired microwave waveguides 21 propagating the microwave generated in the microwave generator 20 and branching from the microwave generator 20; the microwave introducing windows 22 provided to the paired microwave waveguides 21; and the ECR plasma chamber 25 into which the microwave is introduced from the microwave introducing windows 22, and the microwave introducing windows 22 are provided on the side surfaces of the ECR plasma chamber 25.

Further, the cylindrical target TA is arranged to be in contact with the ECR plasma chambers 25, and the cylindrical target TA is mounted on a cylindrical-target mounting section 27. The cylindrical target TA used here is a component to be bombarded with the positive ions (nitrogen ions or argon ions) making the ECR plasma generated in the ECR plasma chamber 25, and is fixed to the cylindrical-target mounting section 27. Additionally, the cylindrical-target mounting section 27 is electrically connected to a sputtering power supply 28, and receives power supplied from the sputtering power supply 28. Consequently, the power is supplied to the cylindrical target TA fixed to the cylindrical-target mounting section 27. Thus, the sputtering power supply 28 functions as a power supplying section (first power supplying section) capable of supplying the power to the cylindrical target TA. The sputtering power supply 28 is made of, for example, a high-frequency power supply, a direct-current power supply (DC power supply), or a pulsating direct-current power supply.

The film forming apparatus 1 further includes a magnetron sputtering section 3 connected to the film forming chamber 10. The magnetron sputtering section 3 includes a disk-target mounting section 31 capable of mounting the disk target TA2 thereon, and the disk-target mounting section 31 is provided with a magnetic-field generating magnet 32 functioning as a magnetic-field generating section.

Further, the disk-target mounting section 31 is electrically connected to a sputtering power supply 33, and receives power supplied from the sputtering power supply 33. Consequently, the power is supplied to the disk target TA2 mounted on the disk-target mounting section 31. Thus, the sputtering power supply 33 functions as a power supplying section (second power supplying section) capable of supplying the power to the disk target TA2. The sputtering power supply 33 is made of, for example, a high-frequency power supply, a direct-current power supply (DC power supply), or a pulsating direct-current power supply.

In this case, a first power value of the power supplied from the sputtering power supply 28 to the cylindrical target TA is lower than a second power value of the power supplied from the sputtering power supply 33 to the disk target TA2 due to a difference between a mechanism for generating the ECR plasma in the ECR sputtering section 2 and a mechanism for generating the plasma (which is different in density from the ECR plasma) in the magnetron sputtering section 3. That is, while the ECR plasma is generated under use of not the power supplied from the sputtering power supply 28 to the cylindrical target TA but the electron cyclotron resonance phenomenon, the plasma in the magnetron sputtering section 3 is generated under use of the power supplied from the sputtering power supply 33 to the disk target TA2. Thereby, the first power value of the power supplied from the sputtering power supply 28 to the cylindrical target TA is lower than the second power value of the power supplied from the sputtering power supply 33 to the disk target TA2.

As described above, the plasma which is different in density from the ECR plasma is generated in the magnetron sputtering section 3 by the power supplied from the sputtering power supply 33 to the disk target TA2. That is, the magnetron sputtering section 3 functions as a plasma generating section (second plasma generating section) for generating the plasma which is different in density from the ECR plasma.

The disk target TA2 is a component to be bombarded with the positive ions (nitrogen ions or argon ions) making the plasma generated in the plasma generating section (second plasma generating section), and is fixed to the disk-target mounting section 31 via the magnetic-field generating magnet 32.

Note that the magnetron sputtering section 3 is an exemplary unit for achieving the typical sputtering technique, and the unit for achieving the typical sputtering technique may be made of, for example, an RF sputtering section, a DC sputtering section, a pulsed DC sputtering section, or the like instead of the magnetron sputtering section 3.

In the film forming apparatus 1 configured as described above, the target particles (first target particles) emitted by the bombardment of the ions (ions making the ECR plasma) with the cylindrical target TA mounted on the cylindrical-target mounting section 27 and the target particles (second target particles) emitted by the bombardment of the ions (ions making the plasma which is different in density from the ECR plasma) with the disk target TA2 mounted on the disk-target mounting section 31 are deposited on the surface of the substrate SUB.

At this time, in the film forming apparatus 1, a first operation of depositing the first target particles on the substrate SUB and a second operation of depositing the second target particles on the substrate SUB are performed at the same time, and a first deposition speed at which the first target particles are deposited on the substrate SUB is lower than a second deposition speed at which the second target particles are deposited on the substrate SUB.

The film to be deposited on the substrate SUB is, for example, the film with the doping material added to the base material. At this time, the first target particles making the cylindrical target TA are the doping material, and the second target particles making the disk target TA2 are the base material. In a specific example, the base material is gallium nitride, while the doping material is any of silicon, magnesium, and aluminum.

In cross-sectional view, note that the cylindrical-target mounting section 27 is tilted such that a first angle θ1 formed between a normal axis VL1 of the surface of the sample stage 11 and a central axis VL2 of the cylindrical-target mounting section 27 takes a finite value. Further, in cross-sectional view, the disk-target mounting section 31 is opposite to the cylindrical-target mounting section 27 across the normal axis VL1, and is tilted such that a second angle θ2 formed between the normal axis VL1 and a central axis VL3 of the disk-target mounting section 31 takes a finite value. At this time, the cylindrical-target mounting section 27 and the disk-target mounting section 31 are tilted from the normal axis VL1 of the sample stage 11 such that, for example, the first angle θ1 is equal to the second angle θ2.

The film forming apparatus 1 according to the embodied aspect is configured as described above.

### <<Operations of Film Forming Apparatus>>

Subsequently, film forming operations of the film forming apparatus 1 will be described below.

In the film forming apparatus 1, the first operation based on the ECR sputtering section 2 and the second operation based on the magnetron sputtering section 3 are performed at the same time. Thereby, for example, the n-type gallium nitride film, the p-type gallium nitride film, or the AlGaN film can be deposited on the substrate SUB.

The first operation based on the ECR sputtering section 2 will be first described below.

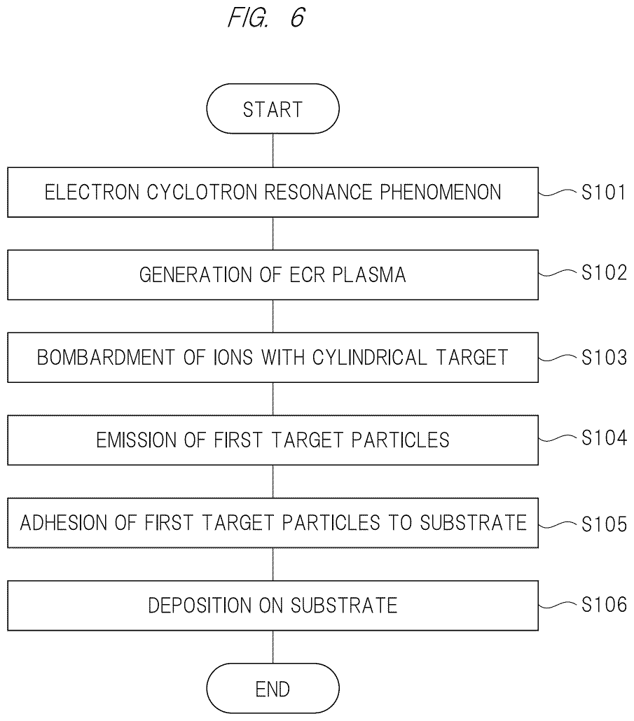

FIG. 6 is a flowchart for explaining a flow of the first operation.

In FIG. 5, first, for example, the mixed gas of nitrogen gas and argon gas is first introduced into the ECR plasma chamber 25 (first plasma generating section). Then, when the magnetic field is generated from the coil 24 (magnetic-field generating section) arranged around the ECR plasma chamber 25, electrons contained in the mixed gas introduced into the ECR plasma chamber 25 are circularly moved by Lorentz force. At this time, the microwave (electromagnetic wave) with the same period (or frequency) as a period (or frequency) of the circular movement of the electrons is generated in the microwave generator 20, and the microwave is introduced from the microwave introducing windows 22 into the ECR plasma chamber 25 via the microwave waveguides 21. Then, the circularly-moving electrons and the microwave resonate, and the microwave energy is efficiently supplied to the circularly-moving electrons (electron cyclotron resonance phenomenon) (S101 in FIG. 6). Consequently, the kinetic energy of the electrons contained in the mixed gas increases, and the mixed gas separates into the positive ions and the electrons. Thereby, the ECR plasma made of the positive ions and the electrons is generated (S102 in FIG. 6).

Next, in FIG. 5, for example, a high-frequency voltage (high-frequency power) is supplied from the sputtering power supply 28 to the cylindrical target TA. In this case, a positive potential and a negative potential are alternately applied to the cylindrical target TA to which the high-frequency voltage is supplied. At this time, while the electrons that are small in mass out of the positive ions and the electrons making the ECR plasma can track the high-frequency voltage applied to the cylindrical target TA, the positive ions that are large in mass cannot track the high-frequency voltage. Consequently, while the positive potential attracting the tracking electrons is cancelled by the negative charges of the electrons, the negative potential remains, and thus, the mean value of the high-frequency voltage shifts from 0 V to the negative potential. This means that, in spite of the application of the high-frequency voltage to the cylindrical target TA, the cylindrical target TA can be regarded to apparently receive application of the negative potential. Thereby, the positive ions are attracted to the cylindrical target TA regarded to apparently averagely receive the application of the negative potential, and then, bombard with the cylindrical target TA (S103 in FIG. 6).

Subsequently, by the bombardment of the positive ions with the cylindrical target TA, the first target particles making the cylindrical target TA receive a part of the kinetic energy of the positive ions, and are emitted from the cylindrical target TA to the internal space of the film forming chamber 10 (S104 in FIG. 6).

Then, some of the first target particles emitted to the internal space of the film forming chamber 10 adhere to the surface of the substrate SUB placed on the sample stage 11 (S105 in FIG. 6). Then, the phenomena are repeated, thereby adhering many first target particles to the surface of the substrate SUB, and, as a result, the first target particles are deposited on the surface of the substrate SUB (S106 in FIG. 6).

The first operation in the film forming apparatus 1 is performed as described above.

Next, the second operation based on the magnetron sputtering section 3 will be described.

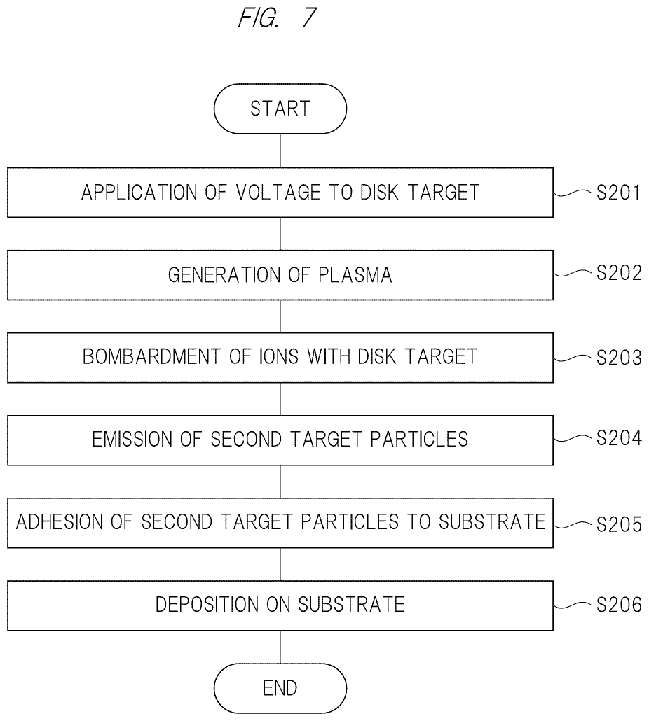

FIG. 7 is a flowchart for explaining a flow of the second operation.

First, in FIG. 5, a voltage is applied from the sputtering power supply 33 to the disk-target mounting section 31. Thereby, the voltage is applied to the disk target TA2 mounted on the disk-target mounting section 31 (S201 in FIG. 7). To the contrary, the substrate SUB placed on the sample stage 11 of the film forming chamber 10 is set at a predetermined potential (such as a floating potential). Thus, the disk target TA2 and the substrate SUB are different in potential. Consequently, the mixed gas of nitrogen gas and argon ga supplied to the film forming chamber 10 is plasmarized to generate the plasma between the disk target TA2 and the substrate SUB (S202 in FIG. 7).

In this case, as illustrated in FIG. 5, the disk-target mounting section 31 is provided with the magnetic-field generating magnet 32, and the magnetic field is generated on the surface of the disk target TA2 by the magnetic-field generating magnet 32. And, by the magnetic field, the plasma is concentrated on a region around the surface of the disk target TA2. Thereby, the ions making the plasma efficiently bombard with the disk target TA2 (S203 in FIG. 7).

Subsequently, by the bombardment of the ions with the disk target TA2, the second target particles making the disk target TA2 receive a part of the kinetic energy of the ions, and are emitted from the disk target TA2 to the internal space of the film forming chamber 10 (S204 in FIG. 7).

Then, some of the second target particles emitted to the internal space of the film forming chamber 10 adhere to the surface of the substrate SUB placed on the sample stage 11 (S205 in FIG. 7). Then, the phenomena are repeated, thereby adhering many second target particles to the surface of the substrate SUB, and, as a result, the second target particles are deposited on the surface of the substrate SUB (S206 in FIG. 7).

The second operation in the film forming apparatus 1 is performed as described above.

In the film forming apparatus 1, the first operation and the second operation are performed at the same time. Consequently, both the first target particles and the second target particles are deposited on the surface of the substrate SUB.

For example, when the first target particles are made of the doping material while the second target particles are made of the base material, the film made of the base material with the doping material added thereto is formed on the substrate SUB.

In another specific example, when the first target particles are made of silicon while the second target particles are made of gallium nitride, the n-type gallium nitride film is formed on the surface of the substrate SUB. To the contrary, when the first target particles are made of magnesium while the second target particles are made of gallium nitride, the p-type gallium nitride film is formed on the surface of the substrate SUB. Furthermore, when the first target particles are made of aluminum while the second target particles are made of gallium nitride, the AlGaN film is formed on the surface of the substrate SUB.

By the above-described operations of the film forming apparatus 1, for example, a film forming method including the following steps is achieved. That is, the film forming method includes: a step of mounting the cylindrical target TA onto the cylindrical-target mounting section 27; a step of mounting the disk target TA2 onto the disk-target mounting section 31; a step of generating the ECR plasma; a step of generating the plasma which is different in density from the ECR plasma; and a step of forming a film made of the first target particles and the second target particles onto the substrate SUB by depositing, on the substrate SUB, the first target particles emitted by bombardment of the ions making the ECR plasma with the cylindrical target TA mounted on the cylindrical-target mounting section 27, and by depositing, on the substrate SUB, the second target particles emitted by bombardment of the ions making the plasma with the disk target TA2 mounted on the disk-target mounting section 31.

### Features of Embodied Aspect

Next, the features of the embodied aspect will be described.

The first feature of the embodied aspect is that the film forming apparatus 1 includes the ECR sputtering section 2 and the magnetron sputtering section 3. That is, the first feature is that the film is formed on the substrate SUB by a combination of the ECR sputtering technique under the use of the cylindrical target TA and the magnetron sputtering technique under the use of the disk target TA2.

The first feature is effective in forming, on the substrate SUB, the film with the doping material added to the base material. Specifically, in forming, on the substrate SUB, the film with the doping material added to the base material, the first feature is applied when the ECR sputtering technique is employed for depositing the doping material under the use of the cylindrical target TA made of the doping material and when the magnetron sputtering technique is employed for depositing the base material under the use of the disk target TA2 made of the base material.

Thereby, the voltage applied to the target can be made smaller in the ECR sputtering technique than the magnetron sputtering technique, and thus, for example, the emitted amount of the first target particles from the cylindrical target TA can be easily controlled to be less. This means that the addition amount of the doping material is easily controlled (first advantage) in the case of the cylindrical target TA made of the doping material.

To the contrary, the film forming speed is higher in the magnetron sputtering technique than the ECR sputtering technique. Thus, the high film forming speed of the base material can be secured (second advantage) when the magnetron sputtering technique is employed for depositing the base material under the use of the disk target TA2 made of the base material. In this case, the doping material is the material added to the base material, and is less deposited than the base material, and thus, the high film forming speed is not required. Therefore, the material for which the high film forming speed is required is the base material, and the first feature is effective for improving the film forming speed of the base material.

From the above, the first feature can provide both the first advantage and the second advantage, and thus, the first feature is a technical idea particularly effectively applied to the formation of, on the substrate SUB, the film with the doping material added to the base material.

For example, under the use of the first feature, the n-type gallium nitride film (doping material: silicon, base material: gallium nitride), the p-type gallium nitride film (doping material: magnesium, base material: gallium nitride), or the AlGaN film (doping material: aluminum, base material: gallium nitride) can be formed on the substrate SUB.

At this time, according to the first feature, not the cylindrical target TA but the disk target TA2 may be used as the target of the gallium nitride. In this regard, it is difficult to form the cylindrical target TA made of gallium nitride. Therefore, the first feature using not the cylindrical target TA but the disk target TA2 as the target made of the gallium nitride provides the advantage that the target made of the gallium nitride can be easily formed.

As described above, the first feature is of large technical significance because of providing a technical idea capable of forming the gallium nitride film with the doping material added thereto under the use of not the chemical vapor deposition (CVD) method but the sputtering technique.

Subsequently, the second feature of the embodied aspect is that, for example, as illustrated in FIG. 5, the cylindrical-target mounting section 27 is tilted such that the first angle θ1 formed between the normal axis VL1 of the surface of the sample stage 11 and the central axis VL2 of the cylindrical-target mounting section 27 takes a finite value.

Thereby, according to the second feature, the uniform depositing performance of the first target particles (doping material) on the substrate SUB placed on the sample stage 11 can be made higher than that in a case in which the cylindrical-target mounting section 27 and the sample stage 11 face each other (θ1=0). That is, as a result of the vigorous study, the present inventors have newly found that the uniform depositing performance of the first target particles on the substrate SUB can be improved by tilting the cylindrical-target mounting section 27 from the sample stage 11. Based on the findings, the second feature is employed.

Similarly, the second feature of the embodied aspect is that, for example, as illustrated in FIG. 5, the disk-target mounting section 31 is opposite to the cylindrical-target mounting section 27 across the normal axis VL1, and is tilted such that the second angle θ2 formed between the normal axis VL1 and the central axis VL3 of the disk-target mounting section 31 takes a finite value.

Thereby, according to the second feature, the uniform depositing performance of the second target particles (base material) on the substrate SUB placed on the sample stage 11 can be made higher than that in a case in which the disk-target mounting section 31 and the sample stage 11 face each other (θ2=0). That is, as a result of the vigorous study, the present inventors have newly found that the uniform depositing performance of the second target particles on the substrate SUB can be improved by tilting the disk-target mounting section 31 from the sample stage 11. Based on the findings, the second feature is employed.

In this case, the damage on the substrate SUB is larger in the film forming steps based on the magnetron sputtering section 3 under the use of the disk target TA2 than the film forming steps based on the ECR sputtering section 2 under the use of the cylindrical target TA. This is because the use of the cylindrical target TA can decrease the probability of the bombardment of the recoil positive ions having high energy with the substrate SUB to be smaller than that in the use of the disk target TA2 as described in the chapter <Advantages of Cylindrical Target>. In other words, the use of the disk target TA2 increases the probability of the bombardment of the recoil positive ions having high energy with the substrate SUB to be larger than that in the use of the cylindrical target TA, and thus, increases the damage on the substrate SUB due to the bombardment of the recoil positive ions having high energy.

In this regard, according to the second feature, the disk-target mounting section 31 is tilted such that the second angle θ2 formed between the normal axis VL1 and the central axis VL3 of the disk-target mounting section 31 takes a finite value. That is, according to the second feature, the disk-target mounting section 31 and the sample stage 11 do not face each other. In this case, the probability of the bombardment of the recoil positive ions having high energy with the substrate SUB can be made smaller in the tilt arrangement according to the second feature than the facing arrangement. Thereby, the second feature is also effective in that the damage on the substrate SUB can be made small even in the film forming steps based on the magnetron sputtering section 3 under the use of the disk target TA2.

Next, the third feature of the embodied aspect is that, for example, as illustrated in FIG. 5, the microwave introducing windows 22 are provided on the side surfaces of the ECR plasma chamber 25. In other words, the third feature employs a configuration in which the microwave is introduced into the ECR plasma chamber 25 from the side surfaces of the ECR plasma chamber 25.

Thereby, according to the third feature is advantageous in that the film forming apparatus 1 can be used over a long period. For example, a configuration in which the microwave introducing window is provided on a lower portion (bottom) of the ECR plasma chamber 25 may be discussed. In the configuration, the microwave is introduced into the ECR plasma chamber 25 from the bottom of the ECR plasma chamber 25.

In this case, when the positive ions making the ECR plasma generated in the ECR plasma chamber 25 bombard with the cylindrical target TA provided on the top (exit) of the ECR plasma chamber 25, the first target particles emit from the cylindrical target TA. At this time, the first target particles emitted from the cylindrical target TA adhere to not only the substrate SUB but also the inside of the ECR plasma chamber 25 and the microwave introducing window 22.

In this regard, in the configuration in which the microwave introducing window is provided on the bottom of the ECR plasma chamber 25, the first target particles emitted from the cylindrical target TA easily adhere to the microwave introducing window. Additionally, the more first target particles adhering to the microwave introducing window make difficult it to introduce the microwave into the ECR plasma chamber 25 from the microwave introducing window. Consequently, the configuration in which the microwave introducing window is provided on the bottom of the ECR plasma chamber 25 makes difficult it to use the film forming apparatus 1 over a long period.

To the contrary, the first target particles adhering to the microwave introducing windows 22 can be made less in the configuration in which the microwave introducing windows 22 are provided on the side surfaces of the ECR plasma chamber 25 as illustrated in FIG. 5 than that in the configuration in which the microwave introducing window is provided on the bottom of the ECR plasma chamber 25. This is because it is considerable that the adhering amount of the first target particles is made less when the microwave introducing windows 22 are arranged on not the bottom but the side surfaces of the ECR plasma chamber 25. Further, this is because it is considerable that the anti-adhesive tube 26 is provided on the side surfaces of the ECR plasma chamber 25 as illustrated in FIG. 5, and thus, the anti-adhesive tube 26 contributes to suppression of the adhesion of the first target particles to the microwave introducing windows 22 provided on the side surfaces of the ECR plasma chamber 25.

As described above, according to the third feature of the embodied aspect, the amount of first target particles adhering to the microwave introducing windows 22 can be reduced, and thus, the difficulty in the emission of the microwave from the microwave introducing windows 22 can be reduced. Thereby, the third feature is advantageous in that the film forming apparatus 1 can be used over a long period.

### Effect Validation

The following explanation is made about validation results for the controllability of the addition amount of the doping material by changing the power (voltage) to be applied to the target in forming the film with the doping material added to the base material according to the embodied aspect.

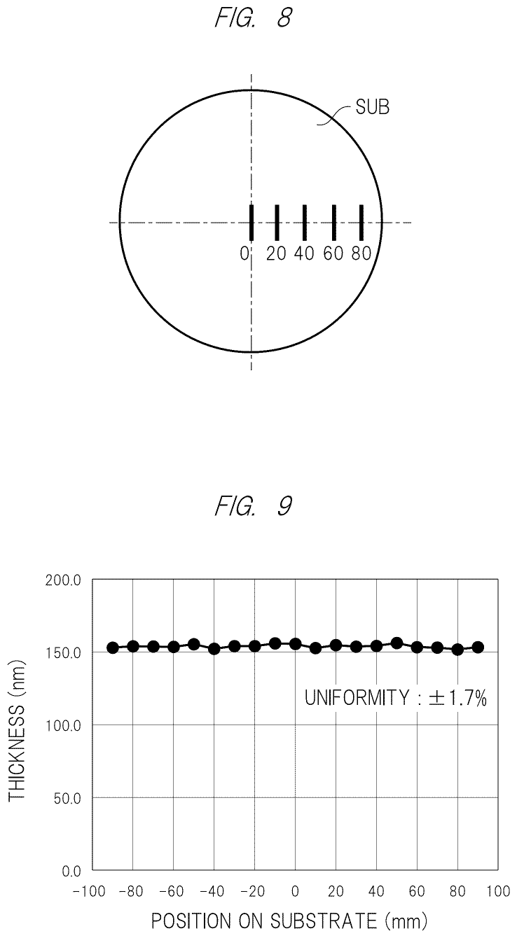

FIG. 8 is a diagram illustrating a portion of the substrate SUB on which the film is formed, the portion being subjected to the SIMS analysis. The substrate SUB is made of, for example, an 8-inch wafer, and FIG. 8 illustrates a center position (0 mm), a position distant by 20 mm from the center position, a position distant by 40 mm from the center position, a position distant by 60 mm from the center position, and a position distant by 80 mm from the center position. For example, in the film forming apparatus 1 of FIG. 5, an amorphous silicon film is formed on the substrate SUB under the use of not the disk target TA2 but the cylindrical target TA made of silicon.

FIG. 9 is a graph illustrating a relationship between a thickness of the amorphous silicon film formed on the substrate SUB and a position on the substrate. As illustrated in FIG. 9, the thickness of the amorphous silicon film is about 150.0 nm at any positions on the substrate, and it is found that the amorphous silicon film is uniformly formed according to the embodied aspect. Particularly, the thickness uniformity is around ±1.7% based on FIG. 9. As described above, it is verified that the film forming apparatus 1 according to the embodied aspect can form the high-uniform film on the substrate SUB from the silicon that is the doping material of the n-type gallium nitride film.

Then, in the film forming apparatus 1 of FIG. 5, the gallium nitride film with silicon added (n-type gallium nitride film) is formed on the substrate SUB under the use of the cylindrical target TA made of silicon and the disk target TA2 made of gallium nitride.

In this case, during the operation (film formation) of the film forming apparatus 1, the power to be supplied to the cylindrical target TA is changed to three levels (power P1>power P2>power P3). Additionally, a silicon concentration distribution in the film thickness direction is measured by the SIMS method at each of the center position (0 mm), the position distant by 20 mm from the center position, the position distant by 40 mm from the center position, the position distant by 60 mm from the center position, and the position distant by 80 mm from the center position.

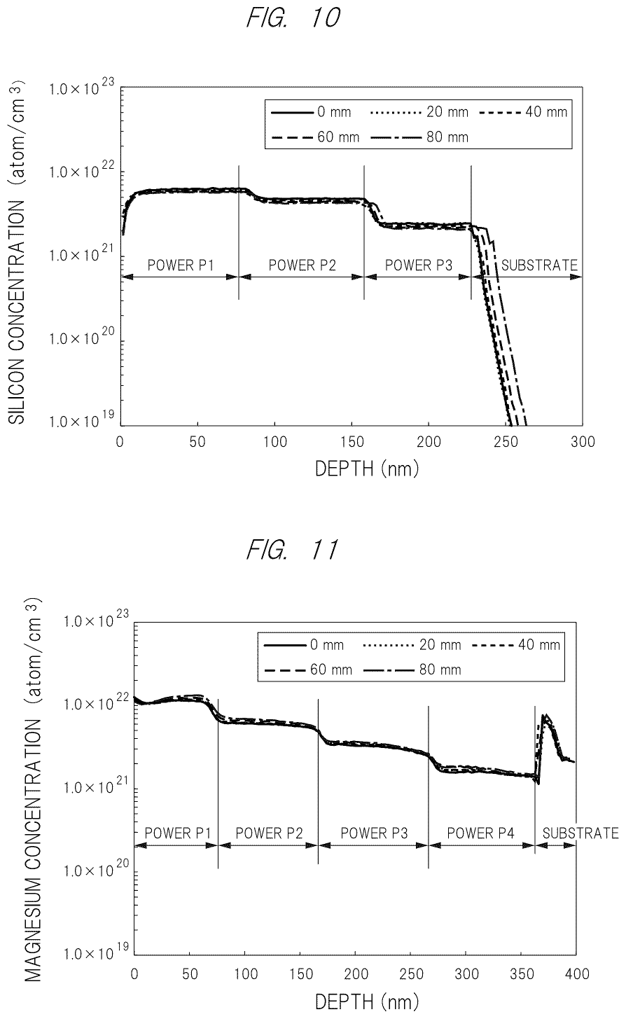

FIG. 10 is a graph illustrating a relationship between the silicon concentration and the depth

It is found from FIG. 10 that the silicon concentration in the film is controllable depending on the power to be supplied to the cylindrical target TA made of silicon. For example, it is found that the silicon concentration in the film can be made higher as the power is higher. Further, as illustrated in FIG. 9, in the film forming apparatus 1 according to the embodied aspect, the amorphous silicon film having high in-plane uniformity is formed, and thus, the silicon concentration in the gallium nitride film in FIG. 10 is also uniform.

From the above description, it is verified that the n-type gallium nitride film having the uniform thickness can be formed at any position on the substrate SUB according to the embodied aspect. It is further verified that the silicon concentration in the n-type gallium nitride film can be controlled by changing the power to be supplied to the cylindrical target TA according to the embodied aspect. Therefore, it can be said that the film forming apparatus 1 is excellent in that the n-type gallium nitride film having any silicon concentration can be formed with the high in-plane uniformity on the substrate SUB.

Next, the following explanation is about an example in the film forming apparatus 1 of FIG. 5 in which the gallium nitride film with magnesium added (p-type gallium nitride film) is formed on the substrate SUB under the use of the cylindrical target TA made of magnesium and the disk target TA2 made of gallium nitride.

In this case, during the operation (film formation) of the film forming apparatus 1, the power to be supplied to the cylindrical target TA is changed to four levels (power P1>power P2>power P3>power P4). Additionally, a magnesium concentration distribution in the film thickness direction is measured by the SIMS method at each of the center position (0 mm), the position distant by 20 mm from the center position, the position distant by 40 mm from the center position, the position distant by 60 mm from the center position, and the position distant by 80 mm from the center position.

FIG. 11 is a graph illustrating a relationship between the magnesium concentration and the depth.

It is found from FIG. 11 that the magnesium concentration in the film is controllable depending on the power to be supplied to the cylindrical target TA made of magnesium. For example, it is found that the magnesium concentration in the film can be made higher as the power is higher. Further, the magnesium concentration in the gallium nitride film is also uniform.

From the above description, it is verified that the p-type gallium nitride film having the uniform thickness can be formed at any position on the substrate SUB according to the embodied aspect. It is further verified that the magnesium concentration in the p-type gallium nitride film can be controlled by changing the power to be supplied to the cylindrical target TA according to the embodied aspect. Therefore, it can be said that the film forming apparatus 1 is excellent in that the p-type gallium nitride film having any magnesium concentration can be formed with the high in-plane uniformity on the substrate SUB.

Next, the following explanation is about an example in the film forming apparatus 1 of FIG. 5 in which the gallium nitride film with aluminum added (AlGaN film) is formed on the substrate SUB under the use of the cylindrical target TA made of aluminum and the disk target TA2 made of gallium nitride.

In this case, during the operation (film formation) of the film forming apparatus 1, the power to be supplied to the cylindrical target TA is changed to four levels (power P1>power P2>power P3>power P4). Additionally, an aluminum concentration distribution in the film thickness direction is measured by the SIMS method at each of the center position (0 mm), the position distant by 20 mm from the center position, the position distant by 40 mm from the center position, the position distant by 60 mm from the center position, and the position distant by 80 mm from the center position.

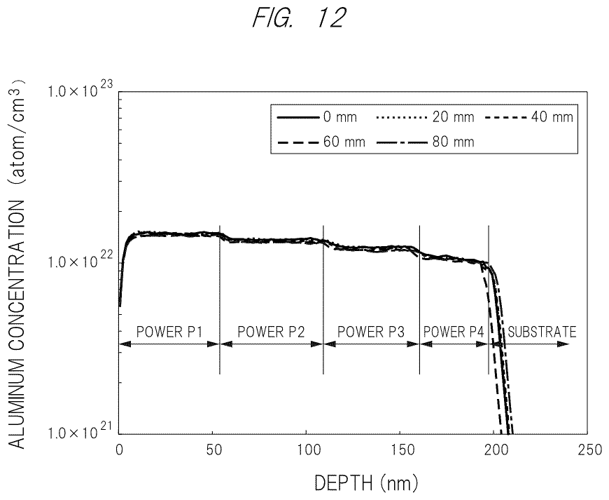

FIG. 12 is a graph illustrating a relationship between the aluminum concentration and the depth.

It is found from FIG. 12 that the aluminum concentration in the film is controllable depending on the power to be supplied to the cylindrical target TA made of aluminum. For example, it is found that the aluminum concentration in the film can be made higher as the power is higher. Further, the aluminum concentration in the gallium nitride film is also uniform.

From the above description, it is verified that the AlGaN film having the uniform thickness can be formed at any position on the substrate SUB according to the embodied aspect. It is further verified that the aluminum concentration in the AlGaN film can be controlled by changing the power to be supplied to the cylindrical target TA according to the embodied aspect. Therefore, it can be said that the film forming apparatus 1 is excellent in that the AlGaN film having any aluminum concentration can be formed with the high in-plane uniformity on the substrate SUB.

As described above, it is confirmed from the SIMS analysis that the doping distribution can be controlled by the power and that the doping distribution is excellent according to the embodied aspect. Particularly, the feature of the tilted-rotation type film forming apparatus according to the embodied aspect is that the film thickness distribution having high uniformity can be achieved, this feature is verified from the results of the SIMS analysis of FIGS. 10 to 12.

In the typical sputtering apparatus, when the power to be applied to the target is lowered, it is difficult to maintain the stable plasma. To the contrary, in the film forming apparatus 1 according to the embodied aspect, the plasma is generated by not the target but the ECR plasma source. Thus, the film forming apparatus 1 according to the embodied aspect is excellent in that the film can be stably doped even if the power to be applied to the target is low.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A film forming apparatus comprising:
a first plasma generating section configured to generate ECR plasma;
a cylindrical-target mounting section configured to mount a cylindrical target to be bombarded with first ions making the ECR plasma generated in the first plasma generating section;
a second plasma generating section configured to generate plasma which is different in density from the ECR plasma;
a disk-target mounting section configured to mount a disk target to be bombarded with second ions making the plasma generated in the second plasma generating section; and
a sample stage configured to place a substrate on which first target particles emitted by the bombardment of the first ions with the cylindrical target mounted on the cylindrical-target mounting section are to be deposited and on which second target particles emitted by the bombardment of the second ions with the disk target mounted on the disk-target mounting section are to be deposited.

2. The film forming apparatus according to claim 1,
wherein in cross-section view, the cylindrical-target mounting section is tilted such that a first angle formed between a normal axis of a surface of the sample stage and a central axis of the cylindrical-target mounting section takes a finite value, and
in cross-section view, the disk-target mounting section is opposite to the cylindrical-target mounting section across the normal axis, and is tilted such that a second angle formed between the normal axis and a central axis of the disk-target mounting section takes a finite value.

3. The film forming apparatus according to claim 1, further comprising:
a first power supplying section configured to supply a power to the cylindrical target; and
a second power supplying section configured to supply a power to the disk target,
wherein a first power value of the power supplied from the first power supplying section is smaller than a second power value of the power supplied from the second power supplying section.

4. The film forming apparatus according to claim 1,
wherein the disk-target mounting section includes a magnetic-field generating section.

5. The film forming apparatus according to claim 1,
wherein a film to be deposited on the substrate is a film with a doping material added to a base material,
the first target particles making the cylindrical target are the doping material, and
the second target particles making the disk target are the base material.

6. The film forming apparatus according to claim 5,
wherein the base material is gallium nitride, and
the doping material is any of silicon, magnesium, and aluminum.

7. The film forming apparatus according to claim 1,
wherein a first deposition speed at which the first target particles are deposited on the substrate is lower than a second deposition speed at which the second target particles are deposited on the substrate.

8. The film forming apparatus according to claim 1,
wherein, in the film forming apparatus, a first operation of depositing the first target particles on the substrate and a second operation of depositing the second target particles on the substrate are simultaneously performed.

9. The film forming apparatus according to claim 1,
wherein the first plasma generating section includes:
a microwave generator configured to generate a microwave;
paired microwave waveguides configured to propagate the microwave generated in the microwave generator and to be provided to branch from the microwave generator;
microwave introducing windows configured to be provided to the paired microwave waveguides, respectively; and
a plasma chamber into which the microwave is introduced from the microwave introducing windows, and
the microwave introducing windows are provided on side surfaces of the plasma chamber.

10. A film forming method comprising steps of:
mounting a cylindrical target onto a cylindrical-target mounting section;
mounting a disk target onto a disk-target mounting section;
generating ECR plasma;
generating plasma which is different in density from the ECR plasma; and
depositing, on a substrate, first target particles emitted by bombardment of first ions making the ECR plasma with the cylindrical target mounted on the cylindrical-target mounting section, and depositing, on the substrate, second target particles emitted by bombardment of second ions making the plasma with the disk target mounted on the disk-target mounting section, to form a film containing the first target particles and the second target particles on the substrate.
